(19) United States
(12) Patent Application Publication
(10) Pub. No.: US 2026/0047159 A1
(43) Pub. Date: Feb. 12, 2026

(54) SEMICONDUCTOR DEVICE AND FABRICATING METHOD THEREOF

(71) Applicant: Fujian Jinhua Integrated Circuit Co., Ltd., Quanzhou City (CN)

(72) Inventor: Huixian LAI, Quanzhou City (CN)

(73) Assignee: Fujian Jinhua Integrated Circuit Co., Ltd., Quanzhou City (CN)

(21) Appl. No.: 18/973,121

(22) Filed: Dec. 9, 2024

(30) Foreign Application Priority Data
Aug. 9, 2024 (CN) 202411090920.7

(51) Int. Cl. H10D 62/17; H10D 64/27; H10D 64/66

(52) U.S. Cl. CPC H10D 62/314; H10D 64/514; H10D 64/518; H10D 64/664

(57) ABSTRACT

A semiconductor device and a method of fabricating the same including a substrate, a first semiconductor layer, a second semiconductor layer, a first insulating layer, a gate dielectric layer, and a gate structure. The first semiconductor layer extends in a first direction. The second semiconductor layer is disposed on the first semiconductor layer and extends in a second direction, the first direction is perpendicular to the second direction, and the first semiconductor layer and the second semiconductor layer are monolithic. The first insulating layer is disposed on the first semiconductor layer. The gate dielectric layer is disposed on a sidewall of the second semiconductor layer and is partially disposed on the first insulating layer. The gate structure is disposed on the gate dielectric layer. Accordingly, the first semiconductor layer and the second semiconductor layer are formed simultaneously, for serving as the source structure and the channel structure respectively.

### BACKGROUND OF THE INVENTION

### 1. Field of the Invention

The present disclosure relates to a semiconductor device and a fabricating method thereof, and more particularly, to a semiconductor device including a vertical channel structure and a fabricating method thereof.

### 2. Description of the Prior Art

The development of semiconductor integrated circuit technology progresses continuously and circuit designs in products of the new generation become smaller and more complicated than those of the former generation. The amount and the density of the functional devices in each chip region are increased constantly according to the requirements of innovated products, and the size of each device has to become smaller accordingly. The conventional planar metal-oxide-semiconductor (MOS) transistor has difficulty when scaling down in the development of the semiconductor device. Therefore, the stereoscopic transistor technology or the non-planar transistor technology that allows smaller size and higher performance is developed to replace the planar MOS transistor for reducing the dimension of the transistor unit and/or improving the operation performance of the transistor unit.

### SUMMARY OF THE INVENTION

One of the objectives of the present disclosure is to provide a semiconductor device where a first semiconductor layer and a second semiconductor layer being monolithic are respectively disposed in a first direction and a second direction being perpendicular to each other, so that, the first semiconductor layer and the second semiconductor layer enable to be respectively configure as a source structure and a channel structure of the semiconductor device, for improving the structural stability and the performance of the semiconductor device thereby.

One of the objectives of the present disclosure is to provide a fabricating method of a semiconductor device, in which a first semiconductor layer and a second semiconductor layer being monolithic are respectively formed in a first direction and a second direction being perpendicular to each other, for serving as a source structure and a channel structure of the semiconductor device respectively, and then, a gate structure is formed on the channel structure. Accordingly, the semiconductor device with improved stability and performance is allowable to be fabricated under a simplified process flow through a gate last forming process.

To achieve the purpose described above, one embodiment of the present disclosure provides a semiconductor device including a substrate, a first semiconductor layer, a second semiconductor layer, a first insulating layer, a gate dielectric layer, and a gate structure. The first semiconductor layer extends in a first direction. The second semiconductor layer is disposed on the first semiconductor layer and extends in a second direction, the first direction is perpendicular to the second direction, and the first semiconductor layer and the second semiconductor layer are monolithic. The first insulating layer is disposed on the first semiconductor layer. The gate dielectric layer is disposed on a sidewall of the second semiconductor layer and is partially disposed on the first insulating layer. The gate structure is disposed on the gate dielectric layer.

To achieve the purpose described above, one embodiment of the present disclosure provides a fabricating method of a semiconductor device including the following steps. A substrate is provided. A first semiconductor layer is formed on the substrate, in a first direction. A second semiconductor layer is formed on the first semiconductor layer, in a second direction, the first direction is perpendicular to the second direction, and the first semiconductor layer and the second semiconductor layer are monolithic. A first insulating layer is formed on the first semiconductor layer. A gate dielectric layer is formed on the first insulating layer, on a sidewall of the second semiconductor layer. A gate structure is formed on the gate dielectric layer.

According to the semiconductor device and the method of fabricating the same, the channel structure and the source structure of the semiconductor device are formed before the gate structure is formed, for example through the same process, so that, the channel structure and the source structure will be monolithic and include the same material, with the channel structure presenting in a cylindrical cross-section in the vertical direction. In this way, the fabricating process of the semiconductor device will be simplified, to form the semiconductor device with simplified structure and better performance, to serve as a dual gate or a gate-all-around thereby.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 is a cross-sectional schematic diagram illustrating a semiconductor device according to a first embodiment of the present disclosure.

FIG. 2 to FIG. 10 are schematic diagrams illustrating a fabricating method of a semiconductor device according to a first embodiment of the present disclosure, wherein:

FIG. 2 is a schematic top view of a semiconductor device after forming a first semiconductor layer and a second semiconductor layer;

FIG. 3 is a schematic cross-sectional view of a semiconductor device after forming a first semiconductor layer and a second semiconductor layer;

FIG. 4 is a schematic top view of a semiconductor device after forming a first insulating material layer;

FIG. 5 is a schematic cross-sectional view of a semiconductor device after forming an insulating material layer;

FIG. 6 is a schematic cross-sectional view of a semiconductor device after forming a metal material layer;

FIG. 7 is a schematic top view of a semiconductor device after forming a gate structure;

FIG. 8 is a schematic cross-sectional view of a semiconductor device after forming a gate structure;

FIG. 9 is a schematic top view of a semiconductor device after forming a second insulating layer; and

FIG. 10 is a schematic cross-sectional view of a semiconductor device after forming a second insulating layer.

FIG. 11 to FIG. 16 are schematic diagrams illustrating a fabricating method of a semiconductor device according to a second embodiment of the present disclosure, wherein:

FIG. 11 is a schematic top view of a semiconductor device after forming a conductive material layer;

FIG. 12 is a schematic cross-sectional view of a semiconductor device after forming a conductive material layer;

FIG. 13 is another schematic cross-sectional view of a semiconductor device after forming a conductive material layer;

FIG. 14 is a schematic top view of a semiconductor device after forming a second insulating layer;

FIG. 15 is a schematic cross-sectional view of a semiconductor device after forming a second insulating layer; and

FIG. 16 is a schematic cross-sectional view of a semiconductor device after forming a drain structure.

### DETAILED DESCRIPTION

To provide a better understanding of the presented invention, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

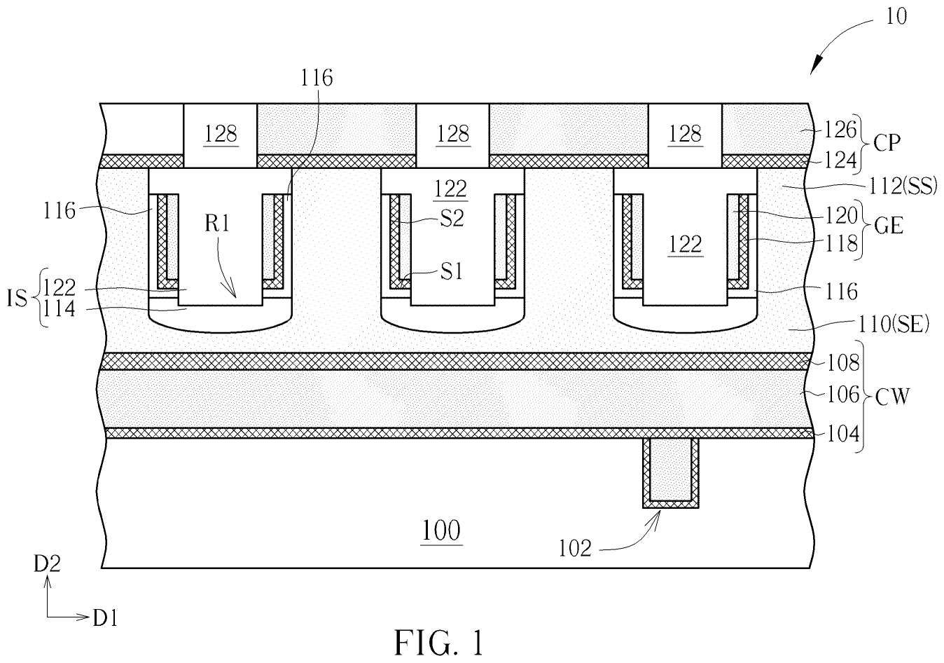

Please refer to FIG. 1. FIG. 1 is a cross-sectional schematic drawing illustrating a semiconductor device 10 according to a first embodiment of the present disclosure. As shown in FIG. 1, the semiconductor device 10 includes a substrate 100, a first semiconductor layer 110, a second semiconductor layer 112, a first insulating layer 114, a gate dielectric layer 116, and a gate structure GE. The substrate 100 for example includes a silicon substrate, a silicon-containing substrate, an epitaxial silicon substrate, a silicon-on-insulator substrate or a substrate being made by other suitable materials, but not limited thereto. People skilled in the arts should fully realize that any required active element or any passive element such as a conductive structure 102 as shown in FIG. 1,may be further formed either on the substrate 100 or in the substrate 100, due to practical produce requirements, but not limited thereto.

The first semiconductor layer 110 and the second semiconductor 112 are disposed on the substrate 100, and are respectively extended in a first direction D1 and a second direction D2 which are perpendicular to each other. The first insulating layer 114 is disposed on a top surface of the first semiconductor layer 110, the gate dielectric layer 116 is disposed on a sidewall of the second semiconductor layer 112, and is partially disposed on the first insulating layer 114. In one embodiment, the first insulating layer 114 and the gate dielectric layer 116 for example include different dielectric materials like silicon oxide, silicon nitride, silicon oxynitride, silicon carbonitride or other suitable materials but not limited thereto. the gate structure GE is also disposed on the sidewall of the second semiconductor layer, over the gate dielectric layer 116. It is noted that, the second semiconductor layer 112 is disposed on the first semiconductor layer 110, and the first semiconductor layer 110 and the second semiconductor layer 112 are monolithic. In one embodiment, the first semiconductor layer 110 and the second semiconductor layer 112 for example all include a semiconductor material like doped polysilicon, doped amorphous silicon, indium zinc oxide (IZO), aluminum zinc oxide (AZO), indium gallium zinc oxide (IGZO), but not limited thereto. With these arrangements, the first semiconductor layer 110 and the second semiconductor layer 112 will serve as a source structure SE and a channel structure SS of the semiconductor device 10 respectively, to physically contact the source structure SE disposed underneath and a conductive pad CP disposed above at the same time. Accordingly, while a threshold voltage is applied to the gate structure GE, the channel structure SS is allowable to be served as a vertical channel structure for electrically connecting the source structure SE and the conductive pad CP, and the gate dielectric layer 116, the gate structure GE, the channel structure SS, and the source structure SE will together form a three-dimensional (3D) transistor component, to function like a dual gate. In this way, due to the arrangement of the first semiconductor layer 110 and the second semiconductor layer 112, the structural stability of the semiconductor device 10 can be improved under a simplified element configuration, and the performance and the operation of the semiconductor device 10 will be effectively enhanced thereby.

Precisely speaking, the gate dielectric layer 116 for example partially extends in the first direction D1, and partially extends in the second direction D2, to obtain a L-shaped cross-section as shown in FIG. 1. The top surface of the gate dielectric layer 116 is coplanar with the top surface of the gate structure GE, and the lateral surface of the gate dielectric layer 116 in the second direction D2 physically contacts the sidewall of the second semiconductor layer 112, and the bottom surface of the gate dielectric layer 116 in the first direction D1 physically contacts the top surface of the first insulating layer 114. The first insulating layer 114 is disposed below the gate dielectric layer 116, and the bottom surface of the first insulating layer 114 physically contacts the top surface of the first semiconductor layer, and the lateral surface of the first insulating layer 114 is vertical aligned with the lateral surface of the gate dielectric layer 116 and physically contacts a portion of the sidewall of the second semiconductor layer 112. The first insulating layer 114 further includes a recess R1 being sunken downwardly from the top surface thereof, with a side of the recess R1 being vertically aligned with the sidewall of the gate structure GE, and physically contacting a first surface S1 in the first direction D1 and a second surface S2 in the second direction D2 of the gate dielectric layer 116 at the same time.

Further in view of FIG. 1, the semiconductor device 10 further includes a metal wire CW, a second insulating layer 122, and an insulating layer 128 disposed on the substrate 100. The metal wire CW is disposed between the first semiconductor layer 110 and the substrate 100, to simultaneously contacts the first semiconductor layer 110 and the conductive structure 102 disposed within the substrate 100. The metal wire CW, the gate structure GE, and the conductive pad CP for example respectively include a multilayer structure. For example, the metal wire CW for example includes a barrier layer 104, a conductive layer 106 and a barrier layer 106 stacked in sequence in the second direction D2, the gate structure GE for example includes a barrier layer 118 and a conductive layer 120 stacked in sequence in the first direction D1, and the conductive pad CP for example includes a barrier layer 124 and a conductive layer 126 stacked in sequence in the second direction D2. In one embodiment, the barrier layer 104, the barrier layer 118, and the barrier layer 124 for example all include the same conductive barrier material like titanium (Ti), titanium nitride (TiN), tantalum (Ta), tantalum nitride (TaN), tungsten nitride (WN), or other suitable conductive barrier material, and the conductive layer 106, the gate layer 120, and the conductive layer 126 all include the same metal material like copper, aluminum, tungsten or other suitable low-resistance metal materials, but not limited thereto.

The second insulating layer 122 is disposed on the first insulating layer 114, and the insulating layer 128 is further disposed on the second insulating layer 122, and the conductive pad CP is disposed in the insulating layer 128, to physically contact the top surface of the second semiconductor layer 112. It is noted that, in the present embodiment, a portion of the second insulating layer 122 overlays the gate dielectric layer 116 and the gate structure GE, and which is sandwiched between the conductive pad CP and the gate structure GE. In one embodiment, the second insulating layer 122 and the insulating layer 128 for example include different dielectric materials such as silicon oxide, silicon nitride, silicon oxynitride, silicon carbonitride, or other suitable materials, and the second insulating layer 122 preferably includes a dielectric material being the same as that of the first insulating layer 144, but not limited thereto. Accordingly, the first insulating layer 114, and the second insulating layer 122 stacked in sequence will together form an insulating spacer IS of the semiconductor device 10, with the insulating spacer IS surrounding the gate structure GE for effective isolating the gate structure GE from other elements adjacent thereto, such that, the structure and the functions of the gate structure GE will be improved thereby.

In other words, through arranging the first semiconductor layer 110 and the second semiconductor layer 112 which are monolithic to serve as the source structure SE and the channel structure SS respectively, the semiconductor device 10 of the present embodiment is allowable to configure as a vertical channel structure under the simplified configuration and better stability, and the channel structure SS of the semiconductor device 10 in the present embodiment enables to function like a dual gate for achieving better operation and performance.

In order to make people skilled in the art of the present disclosure easily understand the semiconductor device of the present disclosure, the fabricating method of the semiconductor device 10 in the present disclosure will be further described below.

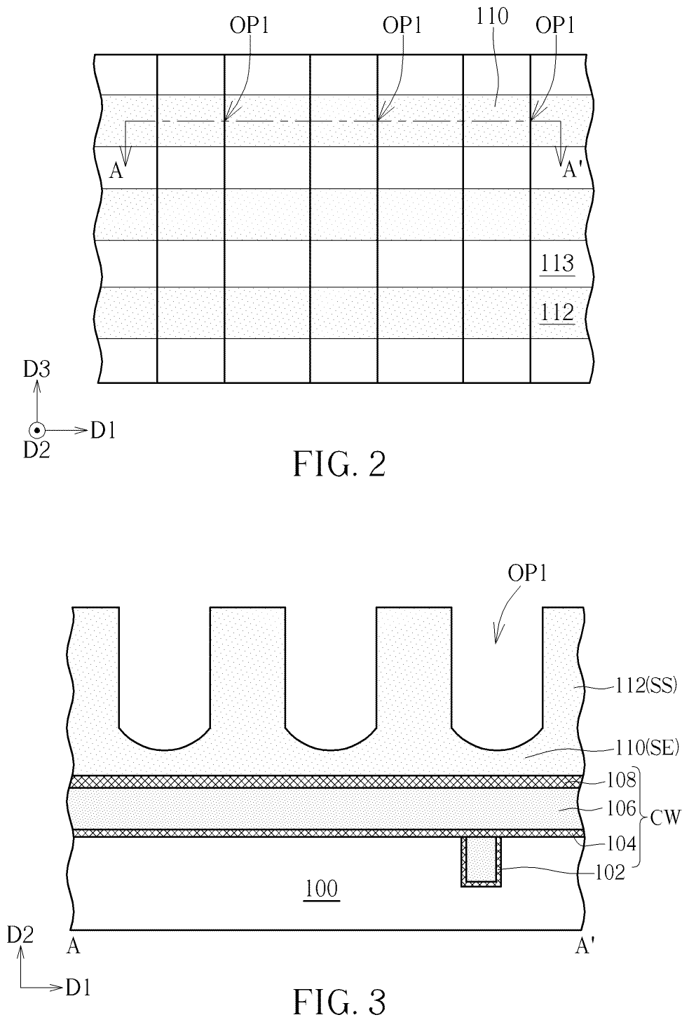

Please refer to FIG. 2 to FIG. 11, illustrating schematic diagrams of a fabricating method of the semiconductor device 10 according to the first embodiment in the present disclosure. Firstly, as shown in FIG. 2 and FIG. 3, a film forming process, such as a chemical vapor deposition process, a physical vapor deposition process, or other suitable approaches, is performed to sequentially form the barrier layer 104, the conductive layer 106, the barrier layer 108, and a semiconductor material layer (not shown in the drawings) on the substrate 100, with the barrier layer 104, the conductive layer 106, and the barrier layer 108 together forming the metal wire CW to physically contact the conductive structure 102 formed within the substrate through the barrier layer 104. The semiconductor material layer for example extends in the first direction D1 and which is alternately arranged with an insulating layer 113 in a third direction D3 being perpendicular to the first direction D1. In one embodiment, the semiconductor material layer for example includes a semiconductor material like doped polysilicon, doped amorphous silicon, indium zinc oxide, aluminum zinc oxide or indium gallium zinc oxide, and the insulating layer 113 for example includes a dielectric material like silicon oxide, silicon nitride, silicon oxynitride, silicon carbonitride, but not limited thereto.

Next, a patterning process is performed through a mask (not shown in the drawings), to form a plurality of trenches (not shown in the drawings) simultaneously penetrating through the semiconductor material layer and the insulating layer 113 in the third direction D3, to form a plurality of openings OP1 in the semiconductor material layer, as shown in FIG. 2 and FIG. 3. Then, the mask is completely removed. Precisely speaking, as shown in FIG. 3, the openings OP1 penetrate through a portion of the semiconductor material layer, so that, the semiconductor material layer being not penetrated by the openings OP1 will entirely overlay the barrier layer 108, to form the first semiconductor layer 110, and the semiconductor material layer partially penetrated by the openings OP1 will be disposed on the first semiconductor layer 110, to form the second semiconductor layer 112 extending in the second direction D2. Accordingly, the first semiconductor layer 110 and the second semiconductor layer 112 will be monolithic and include the same material, and which can be served as the source structure SE and the channel structure SS of the semiconductor device 10 respectively, in the subsequent process.

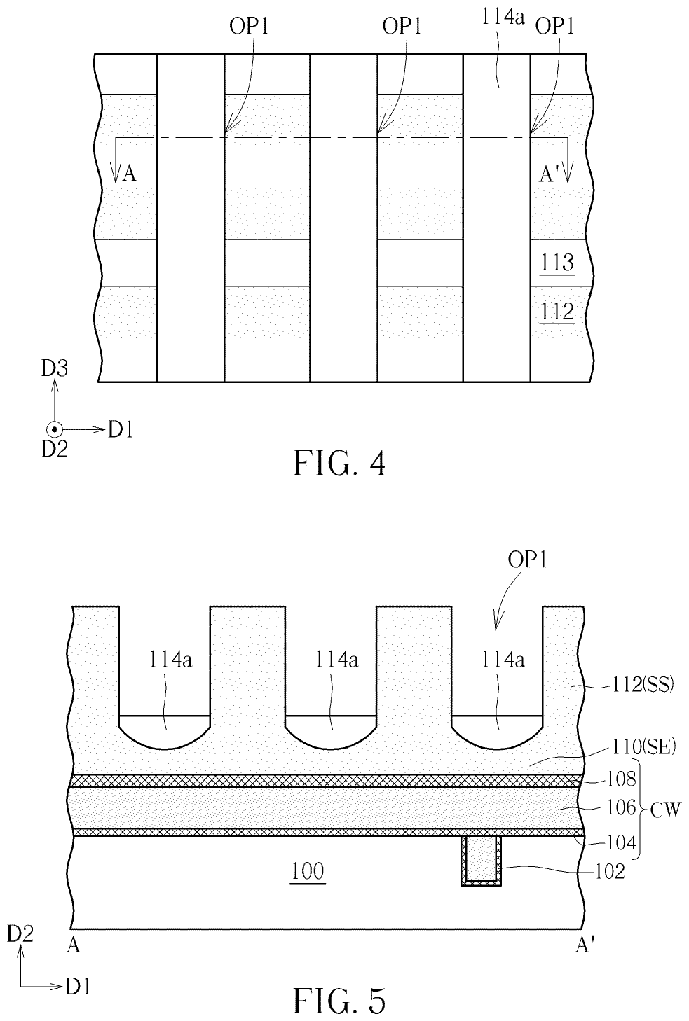

As shown in FIG. 4 and FIG. 5, a deposition process and an etching back process are performed on the substrate 100, to form a first insulating material layer 114a in the trenches, with the first insulating material layer 114a being formed at the bottom of the openings OP1, to partially fill up the openings OP1.

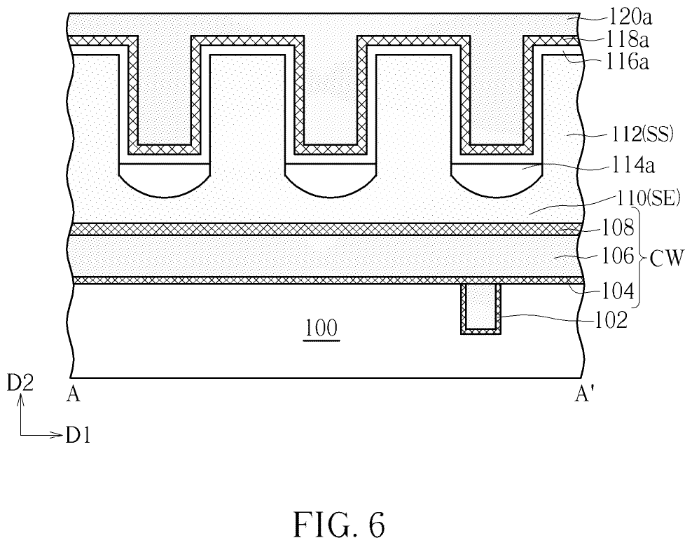

As shown in FIG. 6, a film forming process, such as a chemical vapor deposition process, a physical vapor deposition process, or other suitable approaches, is performed to sequentially form a gate dielectric material layer 116a, a barrier material layer 118a and a conductive material layer 120a, partially within the openings OP1 and partially outside the openings OP1. The conductive material layer 120a fills in the openings OP1 and partially overlays the top surface of the second semiconductor layer 112. In one embodiment, the gate dielectric material layer 116a for example includes a dielectric material like silicon oxide, silicon nitride, silicon oxynitride, or silicon carbonitride, and preferably including a material being different from that of the first insulating material layer 114, but not limited thereto.

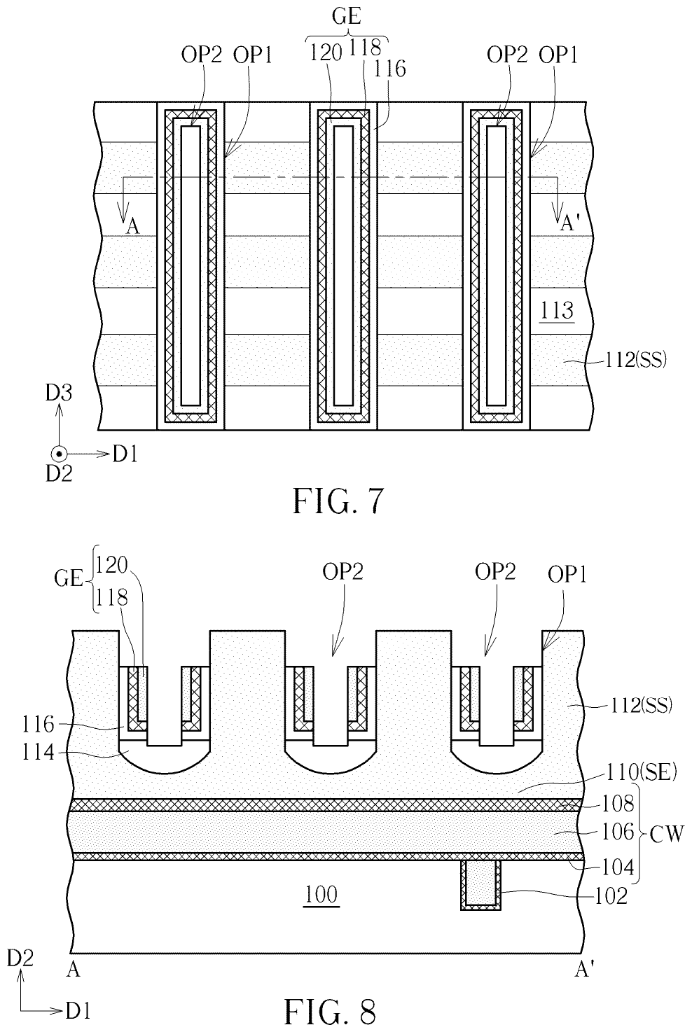

As shown in FIG. 7 and FIG. 8, a planarization process such as a chemical polishing process or other suitable approaches is performed, to remove the conductive material layer 120a, the barrier material layer 118a and the gate dielectric material layer 116a outside the openings OP1, and a dry etching process is performed through another mask (not shown in the drawings), to further remove the conductive material layer 120a, the barrier material layer 118a, and the gate dielectric material layer 116a, and to remove the first insulating material layer 114a disposed under the gate dielectric material layer 116a, thereby forming an opening OP2 with a bottom surface being lower than the first insulating material layer 114a. While forming the opening OP2, the gate dielectric layer 116 and barrier layer 118 both in a L-shaped are simultaneously formed at two sides of the opening OP2, and the conductive layer 120 is formed on the barrier layer 118, and the first insulating layer 114 is formed at the bottom of the opening OP2. Accordingly, the barrier layer 118 and the conductive layer 120 will together form the gate structure GE of the semiconductor device 10, and the gate structure GE and the gate dielectric layer 116 are both disposed on the sidewall of the second semiconductor layer. Then, the another mask is completely removed. It is noted that since the barrier material layer 118a and the gate dielectric material layer 116a are conformally and entirely formed in the trenches, the gate structure GE formed correspondingly is in a stripe shape through a top view as shown in FIG. 7, to physically contact plural channel structures SS at the same time.

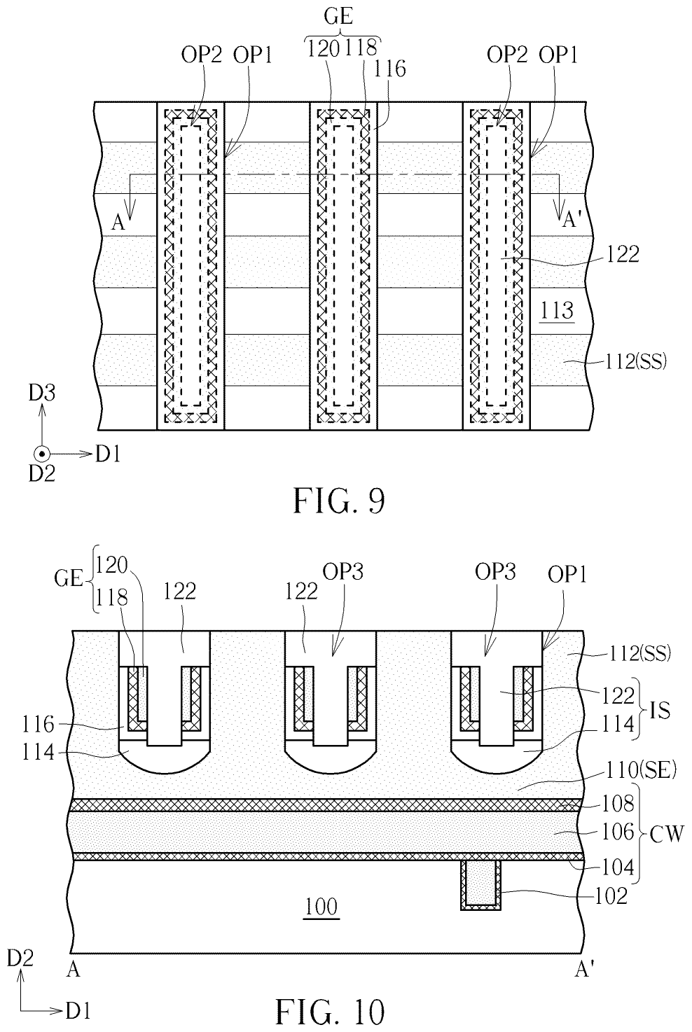

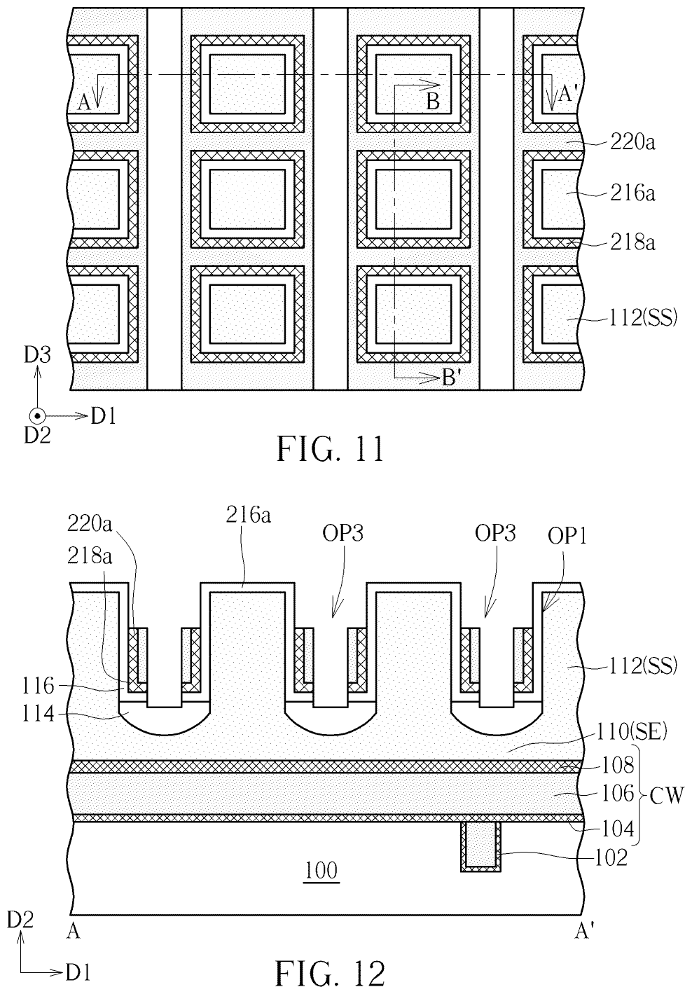

As shown in FIG. 9 and FIG. 10, a deposition process and an etching back process are further performed, to form the second insulating layer 122 filled up the openings OP2. In one embodiment, the second insulating layer 122 preferably includes a dielectric material being the same as that of the first insulating layer 114, like silicon oxide, silicon nitride, silicon oxynitride, or silicon carbonitride, but not limited thereto. Accordingly, the first insulating layer 114 and the second insulating layer 122 sequentially formed between the gate structures GE will together form the insulating spacer IS, for effectively isolating the gate structure GE and the element adjacent thereto. Then, the function and the structure of the gate structure GE will therefore be improved. After that, the conducive pad CP and the insulating layer 128 are formed on the second semiconductor layer 112, with the bottom surface of the conductive pad CP physically contacting the top surface of the second semiconductor layer 112. Through these performances, the semiconductor device 10 as shown in FIG. 1 is formed, and the fabrication of the semiconductor device 10 is accomplished.

According to the fabricating method of the present embodiment, the first semiconductor layer 110 extending in the first direction D1 and the second semiconductor layer 112 extending in the second direction D2 are simultaneously formed through patterning the semiconductor material layer, with the first semiconductor layer 110 and the second semiconductor layer 112 respectively serving as the source structure SE and the channel structure SS of the semiconductor device 10, so that, the channel structure SS can present in a cylindrical cross-section extending in the second direction D2, physically contacting the source structure SE disposed underneath and the conductive pad CP disposed above at the same time. In this way, the source structure SE and the channel structure SS of the semiconductor device 10 are allowable to be formed through the same fabricating process, to obtain a monolithic structure and the same semiconductor material. Then, the gate dielectric layer 116, the gate structure GE, the channel structure SS, and the source structure SE will together form a vertical channel structure to function like a dual gate for achieving better operation and performance. Thus, the fabrication of the semiconductor device 10 is successfully simplified, to form the semiconductor device 10 with simplified configuration and better stability.

People in the art should fully realize that the semiconductor device and the fabricating method thereof are not limited to the aforementioned embodiment and may include other examples or may be achieved through other strategies to meet practical product requirements. The following description will detail the different embodiments of the semiconductor device and fabricating method thereof in the present disclosure. To simplify the description, the following description will detail the dissimilarities among the different embodiments and the identical features will not be redundantly described. In order to compare the differences between the embodiments easily, the identical components in each of the following embodiments are marked with identical symbols.

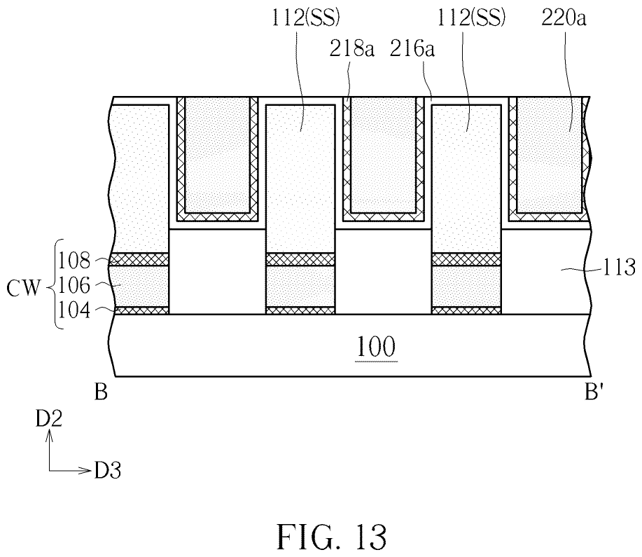

Please refer to FIG. FIG. 11 to FIG. 16, illustrating schematic diagrams of a fabricating method of the semiconductor device 20 according to the second embodiment in the present disclosure. The structure and the fabricating method of the semiconductor device 20 according to the present embodiment is substantially the same as the structure and the fabricating method of the semiconductor device 10 according to the aforementioned first embodiment, and all similarities will not be redundantly described hereinafter. The semiconductor device 20 of the present embodiment and the aforementioned first embodiment is mainly in that a gate dielectric layer 216 with a top surface being higher than the gate structure is formed.

Precisely speaking, as shown in FIG. 11 to FIG. 13, before forming the conductive material layer and the barrier material layer as shown in FIG. 6 of the aforementioned embodiment, the insulating layer 113 disposed at two sides of the second semiconductor layer 112 in the third direction D3 is further removed, and a film forming process, such as a chemical vapor deposition process, a physical vapor deposition process, or other suitable approaches, is further performed to sequentially form a gate dielectric material layer 216a, a barrier material layer (not shown in the drawings) and a conductive material layer (not shown in the drawings) surrounding the second semiconductor layer 112. The gate dielectric material layer 216a, the barrier material layer, and the conductive material layer are partially formed within the opening OP1 and are partially formed outside the opening OP1, and a dry etching process is performed to partially remove the conductive material layer and the barrier material layer, and to form the barrier material layer 218a and the conductive material layer 200 only within the opening OP1 on the gate dielectric material layer 216a. Following these, the conductive material layer 220a, the barrier material layer 218a, the gate dielectric material layer 216a, and the first insulating material layer 114a under the gate dielectric material layer 216a are further removed through a mask (not shown in the drawings), to form an opening OP3, and the mask is then completely removed. Accordingly, while forming the opening OP3, the barrier layer 118 and the conductive layer 120 are simultaneously formed on the gate dielectric material layer 216a, and the barrier layer 118 and the conductive layer 120 will together form the gate structure GE of the semiconductor device 10.

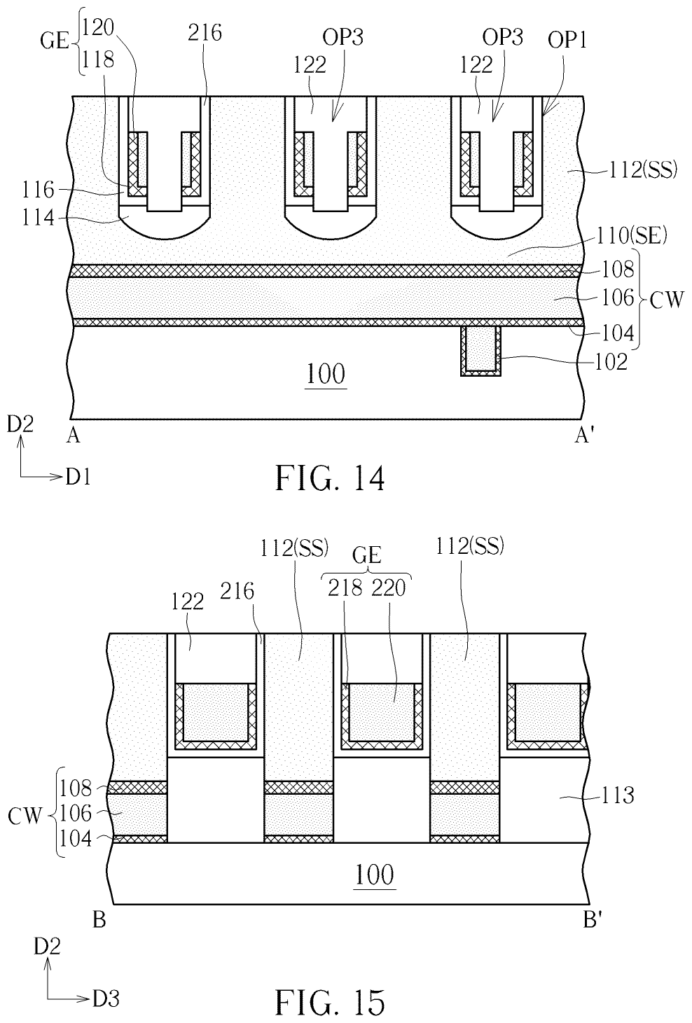

As shown in FIG. 14 and FIG. 15, the conductive material layer 220a and the barrier material layer 218a are further removed till not filling up the opening OP1, so that, a barrier layer 218 and a conductive layer 220 are formed on the gate dielectric material layer 216a at the same time to together form the gate structure GE of the semiconductor device 20. It is noted that, the gate structure GE is disposed at two opposite sides of the second semiconductor layer 112 both in the first direction D1 and in the third direction D3, such that, the gate structure GE is allowable to be formed around the partial sidewall of the second semiconductor layer 112, to function like a gate-all-around device. Then, a film forming process, such as a chemical vapor deposition process, a physical vapor deposition process, or other suitable approaches, is performed to form a second insulating material layer (not shown in the drawings) on the gate dielectric material layer 216a, with the second insulating material layer being formed partially within the opening OP3 and within the opening OP1, and partially outside the opening OP3 and the opening OP1. Next, a planarization process such as a chemical polishing process or other suitable approaches is performed, to remove the second insulating material layer and the gate dielectric material layer 216a formed outside the opening OP3 and the opening OP1, to simultaneously form the second insulating layer 122 and a gate dielectric layer 216. Precisely speaking, the second insulating layer 122 is also formed on the first insulating layer 114, and the second insulating layer 122 and the first insulating layer 114 are both disposed between the plural gate structures GE, to together form the insulating spacer IS of the semiconductor device 20, with the insulating spacer IS effective isolating the gate structure GE from other elements adjacent thereto, so as to gain the improved structure and the functions of the gate structure GE thereby. The gate dielectric layer 216 is formed between the gate structure GE and the second semiconductor layer 112, and the top surface of the gate dielectric layer 216 is coplanar with the top surface of the second insulating layer 122 and the top surface of the second semiconductor layer.

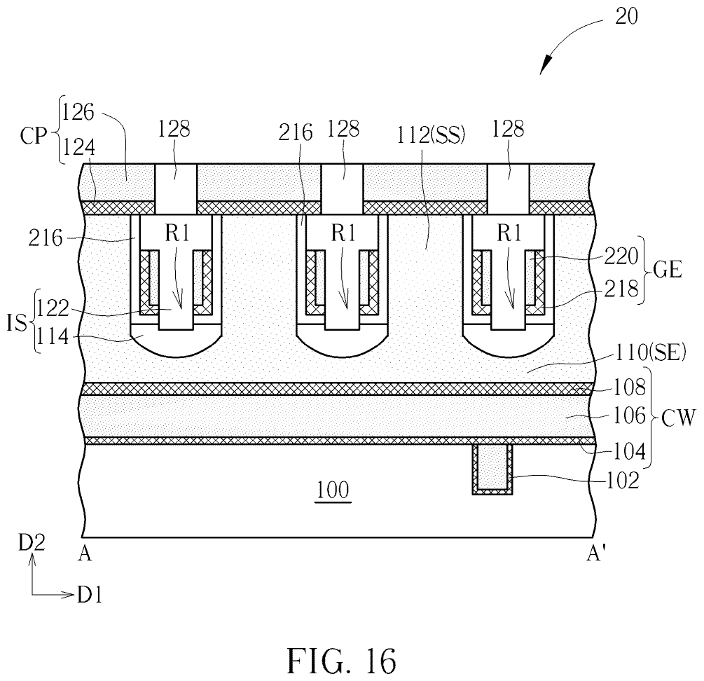

After that, as shown in FIG. 16, the conductive pad CP and the insulating layer 128 are formed on the second semiconductor layer 112, with the bottom surface of the conductive pad CP physically contacting the top surface of the second semiconductor layer 112. Through these performances, the fabrication of the semiconductor device 20 is accomplished. The structure of the semiconductor device 20 in the present embodiment is substantially the same as that of the semiconductor device 10 in the aforementioned first embodiment, and which includes the substrate 100, the first semiconductor layer 110, the second semiconductor layer 112, the first insulating layer 114, and the gate structure GE. The difference between the semiconductor device 20 and the semiconductor device 10 of the first embodiment is mainly in that the top surface of the conductive pad CP further contacts the top surface of the gate dielectric layer 216. In other words, the sidewall of the second semiconductor layer 112 in the second direction D2 is partially covered by the first insulating layer 114, and is partially covered by the gate dielectric layer 216 in the present embodiment. With these arrangements, the channel structure SS being fabricated before the fabrications of gate structure GE or other elements will not be suffered by any damage or defects during the subsequently fabricating processes.

According to the semiconductor device 20 of the present embodiment, the first semiconductor layer 110 and the second semiconductor layer 112 which are monolithic, are served as the source structure SE and the channel structure SS respectively, so that, the source structure SE and the channel structure SS of the semiconductor device 20 will be formed through the same fabricating process, under a simplified process flow. Also, the gate dielectric layer 116, the gate structure GE, the channel structure SS, and the source structure SE of the semiconductor device 20 will together form a vertical channel structure, to function like a gate-all-around device, and the semiconductor device 20 of the present embodiment can achieve better operation and performance under the simplified configuration and better stability.

Overall speaking, according to the semiconductor device and the fabricating method thereof the channel structure is firstly fabricated before the gate structure is formed, and also, the channel structure and the source structure of the semiconductor device are simultaneously formed through the same process, so that, the channel structure and the source structure will be monolithic and include the same material, with the channel structure presenting in a cylindrical cross-section in the vertical direction. In this way, the fabricating process of the semiconductor device will be simplified, to form the semiconductor device with simplified structure and better performance, to serve as a dual gate or a gate-all-around thereby.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a first semiconductor layer, extending in a first direction;
a second semiconductor layer, disposed on the first semiconductor layer and extending in a second direction, the first direction being perpendicular to the second direction, the first semiconductor layer and the second semiconductor layer being monolithic;
a first insulating layer, disposed on the first semiconductor layer;
a gate dielectric layer, disposed on a sidewall of the second semiconductor layer and being partially disposed on the first insulating layer; and
a gate structure, disposed on the gate dielectric layer.

2. The semiconductor device according to claim 1, wherein a bottom surface of the first insulating layer directly contacts a top surface of the first semiconductor layer.

3. The semiconductor device according to claim 1, wherein a lateral surface of the first insulating layer directly contacts the sidewall of the second semiconductor layer.

4. The semiconductor device according to claim 1, a bottom surface of the gate dielectric layer directly contacts a top surface of the first insulating layer, and a lateral surface of the gate dielectric layer directly contacts a lateral surface of the second semiconductor layer.

5. The semiconductor device according to claim 1, wherein the gate dielectric layer comprises a first surface in the first direction and a second surface in the second direction, and the gate structure directly contacts the first surface and the second surface of the gate dielectric layer respectively.

6. The semiconductor device according to claim 1, further comprising:
a conductive pad, disposed on the second semiconductor layer, a bottom surface of the conductive pad directly contacts a top surface of the second semiconductor layer.

7. The semiconductor device according to claim 6, wherein a top surface of the gate dielectric layer directly contacts the bottom surface of the conductive pad.

8. The semiconductor device according to claim 1, wherein the first semiconductor layer and the second semiconductor layer comprise a same semiconductor material.

9. The semiconductor device according to claim 6, further comprising a metal wire disposed under the first semiconductor layer, and the metal wire, the gate structure and the conductive pad respectively comprising:
a conductive layer, wherein the conductive layers of the metal wire, the gate structure and the conductive pad comprise a same metal material; and
a barrier layer, wherein the barrier layers of the metal wire, the gate structure and the conductive pad comprise a same barrier material.

10. The semiconductor device according to claim 1, further comprising:
a second insulating layer, disposed on the first insulating layer and physically contacting the gate dielectric layer and the gate structure.

11. A fabricating method of a semiconductor device, comprising:
providing a substrate;
forming a first semiconductor layer on the substrate, in a first direction;
forming a second semiconductor layer on the first semiconductor layer, extending in a second direction, the first direction being perpendicular to the second direction, the first semiconductor layer and the second semiconductor layer being monolithic;
forming a first insulating layer on the first semiconductor layer;
forming a gate dielectric layer on the first insulating layer, on a sidewall of the second semiconductor layer; and
forming a gate structure on the gate dielectric layer.

12. The fabricating method of the semiconductor device according to claim 11, wherein the first semiconductor layer and the second semiconductor layer are formed simultaneously and comprise a same semiconductor material.

13. The fabricating method of the semiconductor device according to claim 12, further comprising:
forming a semiconductor material layer;
forming a plurality of through holes penetrating through the semiconductor material layer, to simultaneously form the first semiconductor layer and the second semiconductor layer; and
forming a first insulating material layer in the through holes, partially filling in the through holes.

14. The fabricating method of the semiconductor device according to claim 13, forming the gate structure and the gate dielectric layer further comprising:
sequentially forming a gate dielectric material layer, a barrier material layer, and a conductive material layer in the through holes, conformally overlaying the second semiconductor layer and the first insulating material layer;
partially removing the conductive material layer, the barrier material layer and the gate dielectric material layer, to form a conductive layer, a barrier layer and the gate dielectric layer, wherein the conductive layer and the barrier layer together forms the gate structure; and
partially removing the first insulating material layer, to form the first insulating layer, wherein a top surface of the first insulating layer is lower than a bottom surface of the gate dielectric layer.

15. The fabricating method of forming the semiconductor device according to claim 14, further comprising:
forming a second insulating layer on the first insulating layer, wherein the second insulating layer physically contacts the gate dielectric layer, the gate structure and the second semiconductor layer.

16. The fabricating method of forming the semiconductor device according to claim 14, wherein a top surface of the gate dielectric layer is coplanar with a top surface of the gate structure.

17. The fabricating method of forming the semiconductor device according to claim 13, forming the gate structure and the gate dielectric layer further comprising:
sequentially forming a gate dielectric material layer, a barrier material layer, and a conductive material layer in the through holes, conformally overlaying the second semiconductor layer and the first insulating material layer; and
partially removing the conductive material layer and the barrier material layer, to form a conductive layer and a barrier layer, wherein the conductive layer and the barrier layer together forms the gate structure; and
forming a second insulating material layer on the gate dielectric material layer; and
partially removing the second insulating material layer and the gate dielectric material layer, to form a second insulating layer and the gate dielectric layer on the first insulating layer, wherein the second insulating layer physically contacts the gate dielectric layer and the gate structure.

18. The fabricating method of forming the semiconductor device according to claim 17, wherein a top surface of the gate dielectric layer is coplanar with a top surface of the semiconductor layer.

19. The fabricating method of forming the semiconductor device according to claim 17, wherein a top surface of insulating layer is lower than a bottom surface of the gate dielectric layer.

20. The fabricating method of forming the semiconductor device according to claim 17, further comprising:
forming a conductive pad on the second semiconductor layer, wherein a bottom surface of the conductive pad directly contacts a top surface of the second semiconductor layer, and a top surface of the gate dielectric layer directly contacts the bottom surface of the conductive pad.
